(19) United States
(12) Patent Application Publication
(10) Pub. No.: US 2006/0176046 A1
(43) Pub. Date: Aug. 10, 2006

(54) Power meter for biasing an audio amplifier

(76) Inventor: Jason A. Walker, Somerville, MA (US)

Correspondence Address: Jason A. Walker, 9 Bradley Street #2, Somerville, MA, 02145, US

(21) Appl. No.: 11/347,914

(22) Filed: Feb. 6, 2006

Related U.S. Application Data
(60) Provisional application No. 60/650,701, filed on Feb. 7, 2005.

(51) Int. Cl. G01R 11/32

(52) U.S. Cl. 324/142

(57) ABSTRACT

An improved diagnostic meter, of the type used to measure the conduction of a vacuum tube in an audio power amplifier, which provides a display of the average value of instantaneous power dissipated by the tube. A probe containing a current sense resistor and a voltage attenuator interfaces between the tube and the amplifier to sample current through and voltage across the tube. A multiplier circuit computes a product of the sensed current and voltage, and a low-pass filter computes an average of the product. A display represents the average as a numerical value of Watts dissipated by the tube. A further improvement to the meter incorporates a DC-DC converter into the meter's power supply circuitry which allows the meter to be powered from the AC or DC filament supply provided by the amplifier.

### CROSS-REFERENCE TO RELATED APPLICATIONS

This application claims the benefit of PPA Ser. No. 60/650,701, filed 2005 Feb. 7 by the present inventor and entitled, “Power Meter for Biasing an Audio Power Amplifier”.

### CROSS-REFERENCE TO DOCUMENT DISCLOSURE

This application refers to, and incorporates, Document Disclosure No. 558039, filed with a Disclosure Document Deposit Request on 2004 Aug. 2 by the present inventor and entitled, “Power Meter for use in the biasing of a tube-type audio power amplifier”.

### FEDERALLY SPONSORED RESEARCH

Not Applicable

### SEQUENCE LISTING OR PROGRAM

Not Applicable

### BACKGROUND OF THE INVENTION

1. Field of Invention

The present invention relates generally to power measuring apparatus and specifically to an improved electronic diagnostic meter for power amplifier setup and maintenance in the field of vacuum tube type audio amplification.

2. Prior Art

Audio power amplifiers which utilize vacuum tubes, such as electric guitar amplifiers, require a biasing operation or bias adjustment to set the optimal level of electrical conduction for the vacuum tubes used in the power output stage of the amplifier. This bias adjustment is usually performed upon initial installation of the tubes, and may be repeated periodically to account for drift in the conductivity of the tubes which occurs naturally over time. Many such amplifiers provide a bias control which is operated by the user to adjust the conductivity of the tubes. For amplifiers which lack a bias control, such as those with a fixed bias, an equivalent result is accomplished by the pre-selection of tubes with a known conductivity which is suitable to the particular amplifier.

The bias adjustment serves two purposes. The first purpose is to achieve equal current sharing between multiple tubes, such as to balance a push-pull circuit and/or to ensure that all tubes share the workload equally. This is generally desirable to obtain maximum audio output power with a minimum of distortion generated by the output stage of the amplifier. The second purpose is to ensure that each tube, under all foreseeable operating conditions, operates below its maximum average power dissipation limit. This power dissipation limit is provided by the manufacturer of the tube and is quantified in Watts. Operating the tube below this limit is desirable so that the tube does not overheat, resulting in its premature failure and possible damage to the amplifier. Proper performance of the bias adjustment thus results in an amplifier that functions optimally and reliably.

In order to facilitate the bias adjustment, external diagnostic meters are commonly employed to measure conduction of the vacuum tubes. The measurement thereby obtained allows the user to set the bias to a specific level of current flow. These meters generally consist of one or more small inline probes which are inserted between one or more tubes and their respective sockets on the amplifier chassis, with a flexible cable connecting each probe to a hand-held meter which provides a visual indication of current flow through the tube(s). Meters having multiple probes and a single meter circuit usually provide a probe selector switch that allows the user to easily monitor and adjust multiple tubes using the single meter display. Most presently available meters measure only the current flow through the devices, making them suitable for the purpose of achieving current balance or setting a specific predetermined or calculated level of current flow, but not for monitoring power dissipation.

A more detailed discussion of the relationship between current and power dissipation follows:

It is understood that power dissipated by a tube or any other electronic device subjected to a strictly DC (not changing) voltage can be calculated simply by multiplying the value of this DC voltage by the value of resultant DC current through the device (P=VI). When there is an AC (changing) component to either voltage or current, however, the power dissipated by the device changes continually over time and therefore must be calculated at every instant in time. This can be achieved by continuously sampling the instantaneous values of voltage and current, multiplying the samples to derive instantaneous power, and then averaging the results to determine average power.

The proper level of conduction chosen for a tube should therefore account not only for the DC power dissipation (such as when the amplifier is idle and when bias adjustments are typically made), but also for the AC power dissipation (to account for changes in dissipation which occur during normal use of the amplifier). For example, a tube used in one amplifier may be biased below its maximum power dissipation limit when the amplifier is idle, but may dissipate more power and overheat when the amplifier produces output power. Conversely, a tube used in another amplifier may dissipate less power when the amplifier produces output power. The difference depends on variables such as the circuit design of the particular amplifier as well as the level of conduction chosen for the tube by the user.

Unfortunately, average power dissipation of a tube cannot be determined by the user utilizing the present diagnostic meters which only measure DC current. Consequently, the user must compromise by setting a best-guess level of DC current through the tube which it is hoped will result in a good sounding amplifier but which will not cause the tube to overheat. The level of current must be chosen according to either a particular current range pre-determined by the manufacturer of the amplifier to work with most tubes (if published), or a level of current calculated by the user. This calculation is inconvenient and involves de-rating the tube's known dissipation limit by some chosen de-rating factor and dividing the result by a measurement of the DC voltage across the tube. If the de-rating factor chosen is too small then the tube may still overheat during use and result in a poor sounding amplifier and/or premature tube failure and damage to the amplifier. Conversely, if the de-rating factor chosen is too large then the tube may be biased too cold and result in a harsh and poor sounding amplifier. Reliance on the present meters thus results in an uncertain operating condition of the tube during actual usage of the amplifier.

Aiken (The Last Word On Biasing [online], 2003-10-05 [retrieved on 2005-12-12]. Retrieved from the Internet: URL://http://www.aikenamps.com/Biasing.html) discusses at length the importance of biasing for proper power dissipation, but does not provide nor suggest a diagnostic meter suitable for this purpose.

Diagnostic meters such as the ALESSANDRO BIAS AND MATCHING METER (manufactured by Alessandro High-End Products) measure only the level of DC current flow through the tube. All such meters suffer from one or more the following disadvantages:
(a) The user must rely on a pre-determined current setting recommended by the manufacturer of the particular amplifier which may not be published or otherwise available to the user. Further, such a setting may not be appropriate for all tubes such as those having characteristics divergent from the statistical norm for the particular tube type.
(b) The user must calculate the DC current setting, derived from a measurement by the user of the DC voltage across the tube using a separate voltmeter. Further, the setting thereby calculated cannot properly account for the change in power dissipation of the tube during normal use of the amplifier.
(c) The user must access the internal circuitry of the amplifier in order to make the DC voltage measurement, which is inconvenient, requires special skill, and exposes the user to dangerous voltages. Consequently, non-technicians are discouraged from performing this step.
(d) The user cannot determine the real power dissipated by the tube under actual operating conditions because power cannot be measured in real-time, such as while the amplifier is producing audio output.
(e) The user is limited in their choice of a bias setting, because he or she must be excessively conservative in their choice in order to compensate for the unknown power dissipation of the tube and to mitigate the risk of tube failure.
(f) The meters require batteries or an external AC mains-derived power supply to power their internal circuitry.

The WEBER BIAS RITE meter (manufactured by Weber Vintage Sound Technology) improved on the state of the art by incorporating DC voltage measurement capability into the meter, thereby allowing the non-technician to determine the tube voltage without requiring access to the inside of the amp and a separate voltmeter. This design, however, still suffers from all the other aforementioned flaws.

The BIAS KING™ meter (manufactured by Ambient Sound) improved on the state of the art by eliminating the need for either batteries or an external power supply to power the meter. Instead, it derives its power from the AC filament supply provided by many amplifiers to heat the vacuum tube(s). It cannot, however, derive its power from amplifiers which provide a DC filament supply and still suffers from all the other aforementioned flaws.

### OBJECTS AND ADVANTAGES

Accordingly, several objects and advantages of the present invention are:
(a) to simplify the process of biasing a tube amplifier for the non-technical user, by providing a means to set the bias of the tube(s) safely, efficiently, and flexibly, for reliable operation;
(b) to eliminate the need for special knowledge of the particular amplifier to be biased, such as a manufacturer recommended current setting, which may not be appropriate for the particular tube(s) used;
(c) to eliminate the need to measure a DC voltage and further calculate a DC current setting which may not be optimal for the particular tubes during actual use of the particular amplifier;
(d) to eliminate the need to access the internal circuitry of the amplifier and for a separate voltmeter to measure the DC voltage, which is inconvenient, requires special skill, and exposes the user to dangerous voltages;
(e) to increase the user's flexibility in choosing a bias setting by providing a measurement which most accurately indicates the operating condition of the tube(s);
(f) to provide a meter that improves on the prior art by providing continuous measurement of real power dissipated by the tube(s) in Watts, which is the critical parameter of concern to ensure reliable operation of the tube(s);
(g) to provide a meter that improves on the prior art by being able to derive power for its own circuitry from amplifiers having DC as well as AC filament power supplies.

Further objects and advantages will become apparent from a consideration of the ensuing description and drawings.

### SUMMARY

In accordance with the present invention, a power meter comprises an inline probe containing voltage and current sampling means, being connected flexibly to a chassis assembly containing circuitry to multiply and average the samples and to display the results as average power in Watts.

### DRAWINGS—FIGURES

FIG. 1 is a functional diagram, part in schematic form and part in block diagram form, of one simple embodiment of a power meter, illustrating its connections to the user's amplifier and a single vacuum tube.

FIG. 2 is a perspective view of an alternate embodiment of a power meter containing circuitry embodying the invention, and showing its connection to the user's amplifier and four vacuum tubes.

### DRAWINGS—REFERENCE NUMERALS

| | | | |
|---|---|---|---|
| 10 | chassis | 12 | probe |
| 12A | tube socket | 12B | tube base |
| 13 | wires | 14 | vacuum tube |
| 16A | user's amplifier | 16B | bias control |
| 18 | cabling | 20 | resistor |
| 22 | attenuator | 24 | amplifier |
| 26 | multiplier | 28 | low-pass filter |
| 30 | attenuator | 32 | display |
| 34 | rectifier | 36 | filter capacitor |
| 38 | regulator | 40 | DC—DC converter |
| 42 | probe select switch | 44 | function select switch |

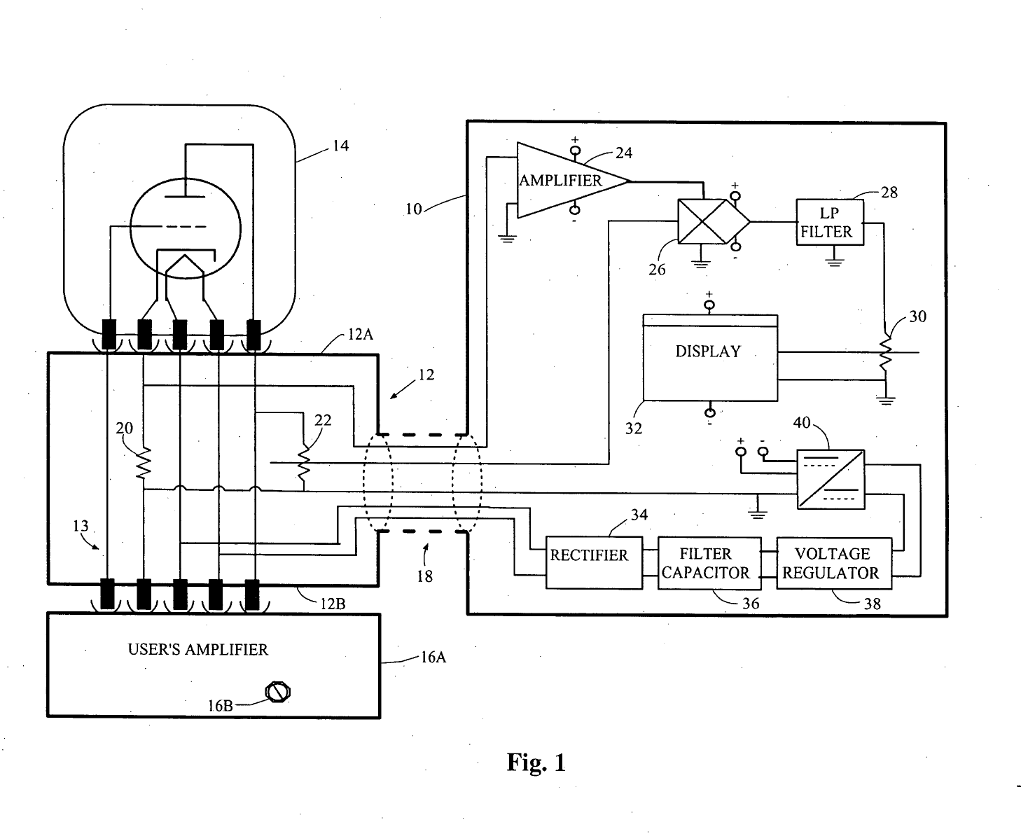

### DETAILED DESCRIPTION—PREFERRED EMBODIMENT—FIG. 1

The method or arrangement of connecting the following electronic components will be well known to those with ordinary skill in the electronic and mechanical arts. Therefore specific details such as power supply bypassing & connections, physical mounting & layout, and other details which do not pertain to the specific operation of the power meter are not covered here.

A power meter of FIG. 1, comprising the most basic embodiment of the invention, is comprised broadly of an inline probe 12 to sample inputs, a meter chassis 10 containing circuitry to process signals and display the output, and an interconnecting cabling 18.

Probe 12 is an assembly comprising a tube socket 12A and tube base 12B, and which contains a current-sampling resistor 20, a high-voltage attenuator 22, and interconnecting wires 13.

Chassis 10 contains meter circuitry comprising a voltage amplifier 24, a voltage multiplier 26, a low-pass filter 28, a scaling attenuator 30, and a digital display 32, as well as power supply circuitry to power the meter circuitry, comprising a full-wave bridge rectifier 34, a filter capacitor 36, a voltage regulator 38, and a DC-DC converter 40.

Interconnecting cabling 18 is a flexible, shielded, multi-conductor cable assembly of a suitable pre-determined length, which provides all electrical connections between probe 12 to the meter chassis 10 and its internal circuitry.

Operation and Connections—FIG. 1

The power meter of FIG. 1 achieves its results as follows: A user inserts probe 12 inline between vacuum tube 14 and its respective socket on a user's amplifier 16A. Wires 13 directly connect all pins of tube socket 12A with corresponding pins of tube base 12B, except for the pins corresponding to the cathode connection of vacuum tube 14 (typically pin 8) between which the current-sampling resistor 20 (typically 1 ohm) is interconnected. As a result, the current flowing through vacuum tube 14 will pass through and be sampled by resistor 20 without significant interference. The high-voltage attenuator 22 (typically a resistive voltage divider of approximately 5M ohms input impedance) is connected between the junction of the pins corresponding to the anode connection of vacuum tube 14 (typically pin 3) and the junction of resistor 20 and tube base 12B, hereby designated meter circuit ground. As a result, the voltage across vacuum tube 14 will be present across and be sampled by attenuator 22 without significant loading. Thus, probe 12, as a whole, causes no significant interference to the normal interaction of vacuum tube 14 and user's amplifier 16A.

Next, the user turns on user's amplifier 16A as is normally done. Electrical connections through cabling 18 facilitate power transfer from the pins of probe 12 corresponding to the filament supply of user's amplifier 16A (typically pins 2 & 7) to the power supply circuitry contained in chassis 10. Rectifier 34 (comprised typically of Schottky diodes such as type STPS140A manufactured by ST Microelectronics) receives either the 6.3V AC or DC voltage of the filament supply and converts the former to a pulsating DC, or simply passes the latter. Filter capacitor 36 and regulator 38 (typically 5V, such as type LF50CDT manufactured by ST Microelectronics) further condition the voltage from rectifier 34 into a pure, regulated DC voltage. DC-DC converter 40 (typically which provides an isolated +/−12V dual supply, such as type NTA0512M manufactured by C&D Technologies) then scales the regulated DC voltage to power the meter circuitry, and isolates the meter circuit ground from that of the filament supply.

With user's amplifier 16A now operating and providing power to the meter's circuitry as described above, resistor 20 generates a low-level voltage signal proportional to the instantaneous current flowing through vacuum tube 14. This low-level signal is then input to amplifier 24 (typically an op-amp type OP-07D manufactured by Texas Instruments), which amplifies it by a factor (such as +26 dB) which is appropriate to drive the first input of multiplier 26 (typically an analog IC of type AD633JR manufactured by Analog Electronics). Attenuator 22 senses the instantaneous high-level voltage present across vacuum tube 14, attenuates it by a factor (such as −46 dB) which is appropriate to drive the second input of multiplier 26. Multiplier 26 computes the product of the first and second inputs, and outputs a scaled signal proportional to the instantaneous power dissipated by vacuum tube 14. Low-pass filter 28 (typically having a time-constant of approximately 0.5 seconds) averages the instantaneous power signal into a signal proportional to the average value of power. Attenuator 30 further scales the average power signal by a factor (such as −20 dB) which is appropriate to drive display 32 (typically an integrated digital display type V125 manufactured by Lascar Electronics). Bias control 16B of user's amplifier 16A can then be adjusted while monitoring display 32, such that vacuum tube 14 is set to operate within its rated power limit during both the idle condition and the active operation of user's amplifier 16A. The above procedure is then repeated for any additional vacuum tubes employed by user's amplifier 16A, such that all vacuum tubes may be biased for equal power dissipation.

It should be understood that equal power dissipation between tubes is virtually equivalent to equal current flow when the amplifier is not producing audio, because the DC voltage present across all tubes is approximately the same during such condition. Therefore, the power meter of FIG. 1 achieves the same result of current balancing as obtained using the prior art.

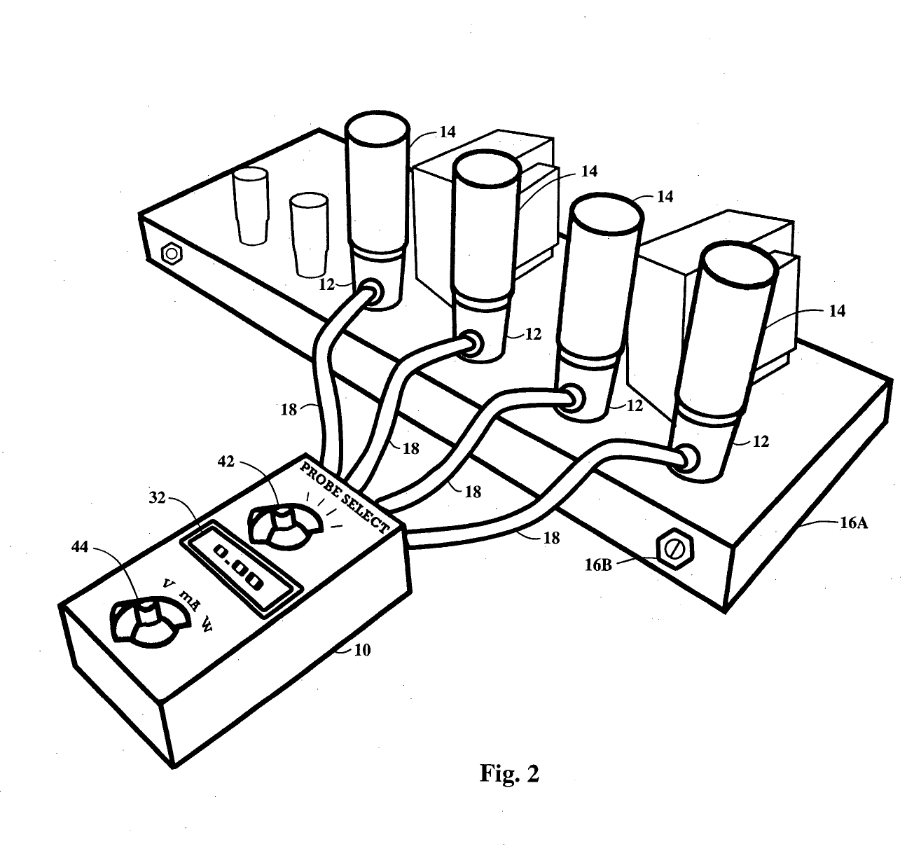

### Description—Alternative Embodiment—FIG. 2

FIG. 2 shows a perspective view of an alternate embodiment of the power meter, having four probes 12, a probe select switch 42, and a three-way function select switch 44. Also shown is its connection to user's amplifier 16A employing four vacuum tubes 14 and having bias control 16B.

Because many amplifiers utilize more than one power tube, it is useful to provide more than one probe 12 and probe select switch 42 to select between the probes. This is common in the prior art and allows greater efficiency, as all measurements can be made in quick succession rather than by the repeated installation and removal of a single probe.

Because the power meter already provides voltage and current sense capability, a more comprehensive embodiment of the power meter may be provided with relative ease by incorporating function select switch 44 to select voltage or current measurement as well as power measurement. The function select switch allows the power meter to be configured like meters of the prior art should the user so desire. The current measurement can provide the greatest accuracy when utilized to match tubes for similar conductivity, because it avoids any additional error inherent to the multiplier circuitry used in the power mode. The voltage measurement can be used to check the power supply of user's amplifier 16A for function, and to evaluate its stiffness or “sag” by noting the change in voltage from no-signal to with-signal operation.

### CONCLUSION, RAMIFICATIONS, AND SCOPE

Thus the reader will see that the power meter of the present invention provides all the functionality of the prior art while adding power measurement capability, as well as, the ability to derive its power from amplifiers with DC heaters.

Although the description above contains many specificities, these should not be construed as limitations on the scope of the invention, but rather as an exemplification of one preferred embodiment thereof. Many other variations are possible. For example:
The power meter may provide alternate ways to power its circuitry, such as by using batteries or an AC mains-derived power supply.
The power meter may comprise multiple meter circuits and displays within the single chassis 10, allowing multiple probes to be monitored simultaneously and eliminating the need for probe select switch 42.
The power meter may provide means to select an output representing the instantaneous values of the measurements.
The power meter may provide connections so that the user can connect their own external display, such as a voltmeter or oscilloscope. These connections may be provided instead of or in addition to display 32.
The power meter may provide an alarm or indication to warn the user in the event that tube 14 exceeds its maximum power dissipation limit.
The power meter circuitry and display may be miniaturized and contained completely within the probe 12, to eliminate the need for chassis 10 and interconnecting cabling 18.
The interconnecting cabling 18 may be eliminated and replaced with wireless circuitry to communicate between probe 12 and the power meter circuitry contained within chassis 10.
The equivalent function of multiplier 26 and low-pass filter 28 may be provided by digital circuitry comprising A/D converters and a microprocessor.
The amplifier 24 and attenuator 30 may be eliminated depending on the drive requirements of alternate multiplier and/or display devices used.
The probe 12 may be constructed to interface with amplifying devices other than vacuum tubes, such as mosfets or other solid-state devices.

It will be understood that numerous modifications and substitutions may be made without departing from the spirit of the invention. Therefore, the invention has been described by way of illustration rather than limitation. Accordingly, the scope of the invention should be determined not by the embodiments illustrated, but by the appended claims and their legal equivalents.

I claim:

1. A method comprising:
(a) measuring an instantaneous magnitude of a current flowing through a controllable electron valve and generating a current signal based on the measurement;
(b) measuring an instantaneous magnitude of a voltage across said controllable electron valve and generating a voltage signal based on the measurement;
(c) generating an instantaneous power signal proportional to an instantaneous magnitude of power dissipated by said controllable electron valve;
(d) generating an average power signal proportional to an average magnitude of power dissipated by said controllable electron valve;
(e) displaying information based on the average power signal;
whereby a user may adjust the power dissipation of said controllable electron valve based on the displayed information.

2. The method of claim 1, wherein said controllable electron valve is operating in an audio power amplifier.

3. The method of claim 1, wherein said controllable electron valve is a vacuum tube.

4. The method of claim 1, wherein generating the instantaneous power signal comprises multiplying the voltage signal by the current signal.

5. The method of claim 1, wherein generating the average power signal comprises averaging the instantaneous power signal over a predetermined time period.

6. The method of claim 5, wherein the time period is about 0.5 seconds.

7. A meter that generates a signal representative of a value of power dissipated by a controllable electron valve used in an amplifier, comprising:
(a) a probe disposed between and in electrical communication with said amplifier and said controllable electron valve and configured to generate a current sense signal and a voltage sense signal;
(b) a meter circuit connected operatively to said probe and configured to respond to said current sense signal and said voltage sense signal and to generate a power signal representative of the value of power dissipated by said controllable electron valve;
whereby a user of said amplifier can adjust the conduction of said controllable electron valve while measuring said power signal.

8. The meter of claim 7 further comprising a display connected operatively to said meter circuit and configured to display information based on said power signal.

9. The meter of claim 7 wherein said probe comprises:
(a) a resistor connected between said amplifier and said controllable electron valve whereby the current through said controllable electron valve also passes through said resistor and which thereby generates said current sense signal which is proportional to the current through said controllable electron valve;
(b) an attenuator connected across said controllable electron valve whereby the voltage across said controllable electron valve is also across said voltage sense attenuator and which thereby generates said voltage sense signal which is proportional to the voltage across said controllable electron valve.

10. The meter of claim 7 wherein said meter circuit comprises:
(a) an analog multiplier IC configured to compute the product of said current sense signal and said voltage sense signal and to generate an instantaneous power signal representative of said product which is proportional to instantaneous power dissipated by said controllable electron valve;
(b) a low-pass filter configured to respond to said instantaneous power signal and to generate said power signal which is proportional to average power dissipated by said controllable electron valve.

11. The meter of claim 7 wherein said meter circuit comprises:
(a) a first A/D converter configured to respond to said current sense signal and to generate a digital current data signal in response thereto;
(b) a second A/D converter configured to respond to said voltage sense signal and to generate a digital voltage data signal in response thereto;
(c) a microprocessor configured to respond to said digital current data signal and said digital voltage data signal and to generate said power signal which is proportional to average power dissipated by said controllable electron valve.

12. The meter of claim 7 wherein said amplifier is an audio power amplifier.

13. The meter of claim 7 further comprising a power supply for the meter which contains a DC-DC converter.

14. The meter of claim 7 further comprising a function select switch to select a measurement to be displayed selected from the group consisting of volts, amperes, and watts.

15. The meter of claim 7 further comprising a plurality of said probe and a probe select switch configured to select between each of the probes.

16. A meter that measures and displays an average value of power dissipated by a vacuum tube used in an audio power amplifier, comprising:
(a) a probe disposed between said audio power amplifier and said vacuum tube and configured to generate a current sense signal and a voltage sense signal;
(b) a meter circuit connected operatively to said probe and configured to compute the average of the product of said voltage sense signal and said current sense signal and to generate an average power signal representative of the average of said product;
(c) a display connected operatively to said meter circuit and configured to provide a visual display which represents the value of said average power signal;
whereby a user of said audio power amplifier can adjust for the proper conduction of said vacuum tube while monitoring said display, and thereby eliminate the need for additional measurements, measuring tools, calculations, or special knowledge of said audio power amplifier.

17. The meter of claim 16 wherein said probe comprises:
(a) a resistor connected in series with said vacuum tube and configured to generate said current sense signal which is proportional to the current through said vacuum tube;
(b) an attenuator connected in parallel with said vacuum tube and configured to generate said voltage sense signal which is proportional to the voltage across said vacuum tube.

18. The meter of claim 17 wherein said meter circuit comprises:
(a) an analog multiplier IC configured to compute said product of said current sense signal and said voltage sense signal and to generate an instantaneous power signal representative of said product which is proportional to the instantaneous power dissipated by said vacuum tube;
(b) a low-pass filter configured to compute the average of said instantaneous power signal and to generate said average power signal which is proportional to average power dissipated by said vacuum tube.

19. The meter of claim 18 further comprising a plurality of said probe and a probe select switch configured to select between each of the probes.

20. The meter of claim 18 further comprising a function select switch to select a measurement to be displayed selected from the group consisting of volts, amperes, and watts.

21. The meter of claim 20 further comprising a plurality of said probe and a probe select switch configured to select between each of the probes.

22. The meter of claim 21 further comprising a power supply for the meter which contains a DC-DC converter.
